(19) United States
(12) Patent Application Publication
(10) Pub. No.: US 2023/0142370 A1
(43) Pub. Date: May 11, 2023

(54) SEMICONDUCTOR PACKAGE MANUFACTURING METHOD

(71) Applicant: SAMSUNG ELECTRONICS CO., LTD., Suwon-si (KR)

(72) Inventors: Kwang Hyeon JEONG, Incheon (KR); Young Joo LEE, Hwaseong-si (KR); Young Bum KIM, Yongin-si (KR); Hyun Mog YOU, Cheonan-si (KR); Dong Joon LEE, Suwon-si (KR); Chae Mook LIM, Yongin-si (KR); Woo Jung JUNG, Seoul (KR)

(73) Assignee: SAMSUNG ELECTRONICS CO., LTD., Suwon-si (KR)

(21) Appl. No.: 17/959,892

(22) Filed: Oct. 4, 2022

(30) Foreign Application Priority Data
Nov. 8, 2021 (KR) 10-2021-0152107

(51) Int. Cl. H01L 23/00; H01L 21/66

(52) U.S. Cl. CPC H01L 24/11; H01L 22/26; H01L 2224/117

(57) ABSTRACT

A semiconductor package manufacturing method is provided. The semiconductor package manufacturing method which uses a semiconductor package manufacturing apparatus including a chuck, a solder device configured to attach solder balls to a substrate provided on the chuck, and a scanning device configured to provide information about a shape of the substrate to the chuck, wherein the chuck comprises an adsorbing portion comprising a plurality of divided regions, each of which is configured to adsorb the substrate, and a driver configured to drive each of the plurality of divided regions, the semiconductor package manufacturing method comprising driving each of the plurality of divided regions to correspond to the shape of the substrate based on the information using the driver.

### CROSS-REFERENCE TO RELATED APPLICATION

This application claims priority from Korean Patent Application No. 10-2021-0152107, filed on Nov. 8, 2021, in the Korean Intellectual Property Office, the disclosure of which is incorporated by reference herein in its entirety.

### BACKGROUND

### 1. Field

The present disclosure relates to a semiconductor package manufacturing method.

### 2. Description of Related Art

Due to demands for high density, reduced thickness, miniaturization, and improved electrical characteristics of a semiconductor package, a thickness of a substrate needs to be reduced and increased electronic components need to be embedded and protected inside the substrate.

However, the reduced thickness may cause the substrate to warp. In particular, when electronic components are embedded within the substrate, a difference in coefficients of thermal expansion after encapsulation of Epoxy Molding Compound (EMC) may cause the substrate to warp.

As the substrate warps, there is a need for stably attaching of solder balls at correct positions.

### SUMMARY

One or more example embodiments provide a semiconductor package manufacturing apparatus capable of stably attaching solder balls to correspond to a substrate having various types of warpage.

One or more example embodiments also provide a semiconductor package manufacturing method capable of stably attaching solder balls to correspond to a substrate having various types of warpage.

According to an aspect of an example embodiment, a semiconductor package manufacturing method which uses a semiconductor package manufacturing apparatus including: a chuck, a solder device configured to attach solder balls to a substrate provided on the chuck, and a scanning device configured to provide information about a shape of the substrate to the chuck, wherein the chuck comprises an adsorbing portion comprising a plurality of divided regions, each of which is configured to adsorb the substrate, and a driver configured to drive each of the plurality of divided regions, the semiconductor package manufacturing method comprising driving each of the plurality of divided regions to correspond to the shape of the substrate based on the information using the driver.

According to an aspect of an example embodiment, a semiconductor package manufacturing method includes: attaching solder balls to a substrate provided on a chuck which includes a plurality of divided regions; providing information about a warpage shape of the substrate to the chuck; and individually controlling positions of each of the plurality of divided regions based on the information.

According to an aspect of an example embodiment, a semiconductor package manufacturing method which uses a semiconductor package manufacturing apparatus including: a chuck; a solder device configured to attach solder balls to a substrate provided on the chuck; and a scanning device configured to provide information about a shape of the substrate to the solder device, wherein the chuck includes an adsorbing portion including a plurality of divided regions, each of which is configured to adsorb the substrate, and a driver configured to drive each of the plurality of divided regions, the scanning device includes a first sensor, the chuck includes a second sensor is provided. The semiconductor package manufacturing method includes: providing the substrate on the chuck; obtaining information indicating a warpage shape of the substrate using the first sensor; identifying a movement distance for each of the plurality of divided regions according to the information; measuring a distance between each of the plurality of divided regions and the substrate using the second sensor; moving each of the plurality of divided regions to an initial position based on the movement distance using the driver; adsorbing the substrate to the chuck based on each of the plurality of divided regions reaching an adsorption distance at which vacuum adsorption is enabled; moving each of the plurality of divided regions back to the initial position; and detaching the substrate from the plurality of divided regions while positioned at the initial position.

### BRIEF DESCRIPTION OF THE DRAWINGS

The above and other aspects and features will be more apparent from the following description of example embodiments with reference to the attached drawings, in which:

FIG. 1 is a diagram which schematically shows a semiconductor package manufacturing apparatus according to some example embodiments;

FIGS. 2A and 2B are diagrams showing a phenomenon in which solder balls are not stably attached to a substrate;

FIG. 3 is a diagram for explaining a scan module of a semiconductor package manufacturing apparatus according to some example embodiments;

FIGS. 4A, 4B, 4C, and 4D are diagrams for explaining deformation of the support member according to the operation of the scan module of the semiconductor package manufacturing apparatus according to some example embodiments;

FIGS. 5A, 5B, 5C, 5D, 5E, and 5F and

FIGS. 6A, 6B, 6C, 6D, 6E, and 6F are diagrams for explaining deformation of the support member according to operation of the second sensor of the semiconductor package manufacturing apparatus according to some example embodiments;

FIGS. 7A and 7B are schematic diagrams showing the support member of the semiconductor package manufacturing apparatus according to some example embodiments;

FIG. 8 is a schematic diagram showing the support member of the semiconductor package manufacturing apparatus according to some example embodiments;

FIGS. 9A, 9B, 9C, 9D and 9E are diagram which schematically show the type of warpage of a substrate according to some example embodiments, and the support member deformed to correspond to each type of warpage;

FIGS. 10 to 12 are diagrams showing the support member of the semiconductor package manufacturing apparatus according to some example embodiments;

FIG. 13 is a diagram for explaining an adsorbing portion and a driving portion of the support member according to some example embodiments;

FIG. 14 is a diagram showing a cross section along a line IT of FIG. 13

FIG. 15 is a diagram which schematically shows the semiconductor package manufacturing method using the semiconductor package manufacturing apparatus according to some example embodiments.

### DETAILED DESCRIPTION

Hereinafter, example embodiments will be described in detail with reference to the accompanying drawings. Like components are denoted by like reference numerals throughout the specification, and repeated descriptions thereof are omitted. Each example embodiment is not excluded from being associated with one or more features of another example or another example embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

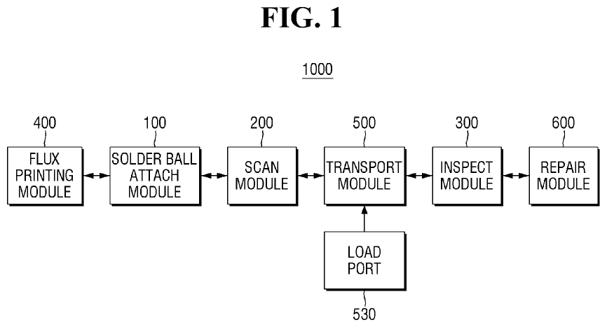

FIG. 1 is a diagram which schematically shows a semiconductor package manufacturing apparatus according to some example embodiments.

Referring to FIG. 1, a semiconductor package manufacturing apparatus 1000 according to some example embodiments may include a flux printing module 400, a solder ball attach module (solder device) 100, a scan module (scanning device) 200, a transport module 500, an inspection module 300, and a repair module 600. At least one of the flux printing module 400, the solder ball attach module 100, the scan module 200, the transport module 500, the inspection module 300, and the repair module 600 may include hardware components, such as a support, a gripping mechanism, an electrical motor, a hydraulic mechanism and/or a processor. Moreover, the processor of the flux printing module 400, the solder ball attach module 100, the scan module 200, the transport module 500, the inspection module 300, and the repair module 600 may control components of the flux printing module 400, the solder ball attach module 100, the scan module 200, the transport module 500, the inspection module 300, and the repair module 600 to perform the described actions functions. The processor may be a hardware processor or a combination of hardware and software modules to perform the described functions, such as a microprocessor.

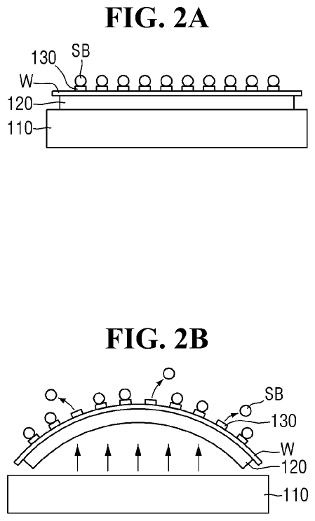

The flux printing module 400 forms a solder paste or a flux 130 on a substrate W in a process of attaching solder balls SB (see FIG. 2). In some example embodiments, the flux printing module 400 may form the flux 130 on a metal pad made of copper (Cu) or the like on the substrate W.

For example, the flux 130 may be a substance that removes an oxide film and chemically activates the solder balls SB so that the solder balls SB may be attached to the metal pad. The flux 130 may be applied onto the metal pad of the substrate W on which the solder balls SB are settled, or may be applied directly onto the solder balls SB.

The solder ball attach module 100 may attach the solder balls SB on the flux 130 formed on the substrate W.

The transport module 500 may transport the substrate W, which may be input through a load port 530, to the solder ball attach module 100. Specifically, the transport module 500 may transport the substrate W to the solder ball attach module 100 and transport the substrate W to which the solder balls SB are attached from the solder ball attach module 100 to the inspection module 300.

The inspection module 300 may inspect the solder balls SB and the substrate W to identify whether the solder balls SB are correctly attached at desired positions. Specifically, it is possible to determine, with respect to various positions of the substrate W, whether the solder balls SB are correctly attached or omitted.

The repair module 600 may supplement the substrate W with the solder balls SB at positions where the inspection module 300 has determined the solder balls SB to be omitted. Specifically, the repair module 600 may fill the omitted solder balls SB at each position of the substrate W.

FIGS. 2A and 2B are diagrams showing a phenomenon in which solder balls are not stably attached to the substrate and detach from the substrate.

First, referring to FIG. 2A, a mold layer 120 is formed on one surface of the substrate W. The mold layer 120 may encapsulate a semiconductor chip and may include, for example, an Epoxy Molding Compound (EMC). However, example embodiments are not limited thereto.

The mold layer 120 for encapsulating the semiconductor chip may be formed after the semiconductor chip is attached to one surface of the substrate W. Further, a wiring layer capable of electrically connecting the solder balls SB and the semiconductor chip may be formed on the substrate W.

The substrate W on which the mold layer 120 is formed may be settled on a support member 110, which may include a chuck. The flux 130 may be formed on another surface of the substrate W which is opposite to the surface of the substrate W facing the mold layer 120, and the solder balls SB may be attached onto the flux 130. The support member 110 may support the substrate W in the process of forming the flux 130 and attaching the solder balls SB.

A process of settling the substrate W may be performed so that the solder balls SB may be attached onto the substrate W. However, when such settling is not performed correctly, many solder balls SB may be incorrectly attached, and may be omitted or the solder balls SB or not be correctly attached at the desired position on the substrate W.

For example, referring to FIG. 2B, when the substrate W has a warpage due to a difference in coefficient of thermal expansion from the mold layer 120, a phenomenon in which the solder balls SB detach from the flux 130 may occur in the process of detaching the substrate W from the support member 110. In this case, because the number of solder balls SB to be replaced increases, there may be a problem of an increase in the number of processes.

In the semiconductor package manufacturing apparatus according to some example embodiments, it is possible to control a shape of the support member 110 to correspond to various warpage types of the substrate W in a series of processes in which the solder balls SB are attached to the substrate W. As a result, the substrate W may be attached to or detached from the support member 110 in a stable manner. As a result, the process of attaching the solder balls SB during the semiconductor package manufacturing process may be made more efficient.

On the other hand, such a semiconductor package manufacturing apparatus and a manufacturing method using the same may also be applied when using not only the unit substrate W in which a warpage occurs, but also a large area substrate (for example, printed circuit board (PCB)), by forming the mold layer 120 after attaching the semiconductor chip.

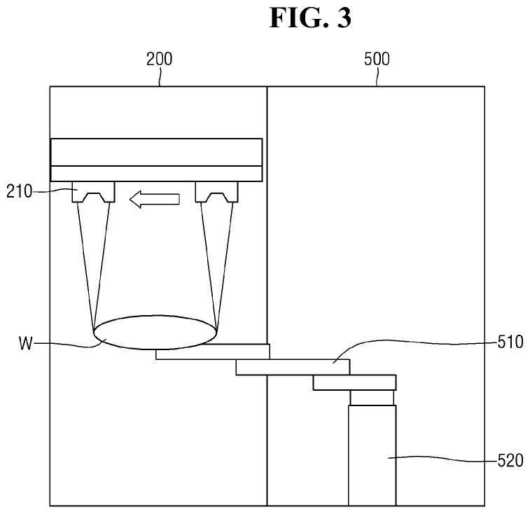

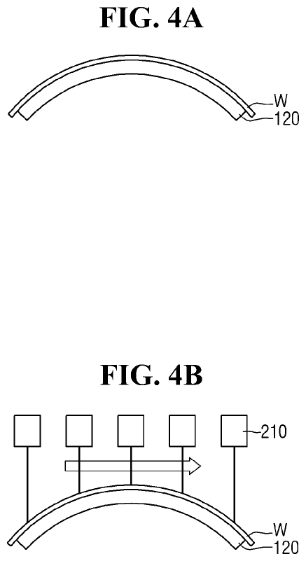

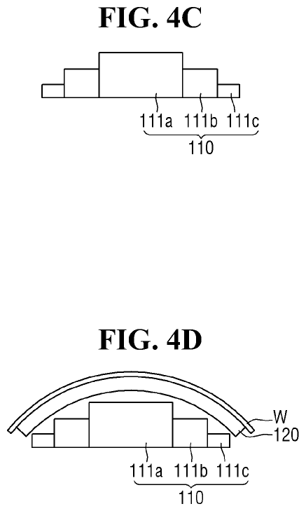

FIG. 3 is a diagram for explaining a scan module of the semiconductor package manufacturing apparatus according to some example embodiments. FIGS. 4A, 4B, 4C, and 4D are diagrams for explaining deformation of the support member according to the operation of the scan module of the semiconductor package manufacturing apparatus according to some example embodiments.

A scan module 200 may transmit information about a shape of the substrate W to the solder ball attach module 100.

Referring to FIGS. 1 and 3 together, the substrate W may be transported to the scan module 200 from the transport module 500 through a transport arm 510 that is supported and driven by a transport arm support portion 520 of the transport module 500.

Specifically, the scan module 200 may measure the warpage of the substrate W transported from the transport module 500 through a 2D plane measurer. The scan module 200 may transmit information about a 2D height contour of the substrate W measured by the scan module 200 to other modules so that the support member 110 may be driven by an optimum movement distance.

In this case, the scan module 200 may include a first sensor 210 that measures information about the 2D height contour of the substrate W. Based on information about the shape of the substrate W measured by the first sensor 210, positions of each of a plurality of divided regions 111a, 111b and 111c of the support member 110 to be described below may be individually controlled. For example, the first sensor 210 may be a laser sensor. However, example embodiments are not limited thereto.

That is, the scan module 200 measures information about the warpage shape of the substrate W in advance, and may transmit information about the warpage type of the substrate W, optimum movement distances of each of the plurality of divided regions 111a, 111b and 111c of the support member 110, and information as to which region moves or the like to the support member 110 of the solder ball attach module 100.

Referring to FIG. 4A, the warped substrate W on which the mold layer 120 is formed may be input to the transport module 500. The transport module 500 may transport the input substrate W to the scan module 200. In this case, the solder balls SB may not be attached to the substrate W.

Referring to FIG. 4B, the scan module 200 may scan the shape of the input substrate W. For example, the scan module 200 may control the first sensor to move to different location with respect to the substrate W, and obtain measurements corresponding to different portions of the substrate W. The scan module 200 may transmit, to the support member 110, information about the warpage type of the substrate W, the optimum movement distances of each of the plurality of divided regions 111a, 111b and 111c of the support member 110, and information as to which region moves to the support member 110 of the solder ball attach module 100. The support member 110 may be driven according to the information received from the scan module 200.

Referring to FIG. 4C, based on the received information, the positions of each of the plurality of divided regions 111a, 111b and 111c of the support member 110 may be adjusted. For example, the height or rotation angle of each of the plurality of divided regions 111a, 111b and 111c may be adjusted. That is, the support member 110 may be deformed to correspond to each of a plurality of regions of the warped substrate W.

Referring to FIG. 4D, the support member 110 deformed for each of the plurality of divided regions 111a, 111b and 111c to correspond to each of the plurality of regions of the warped substrate W may vacuum-adsorb the substrate W.

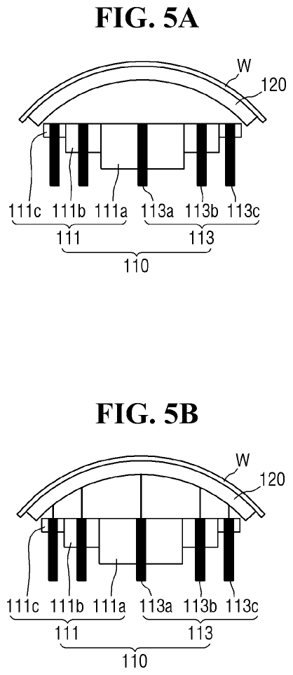

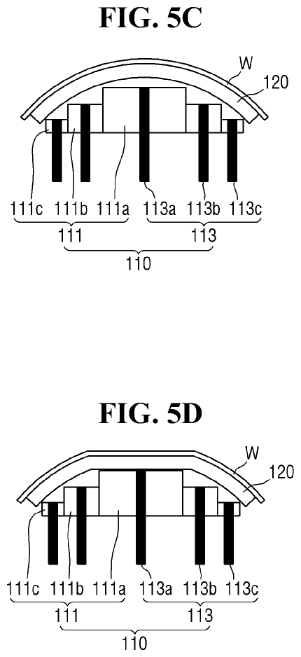

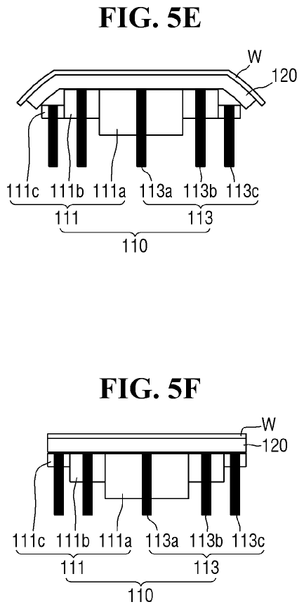

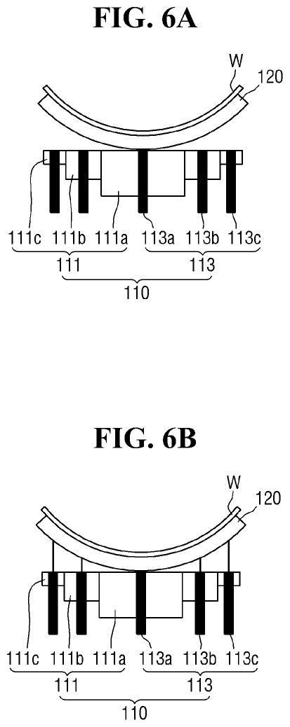

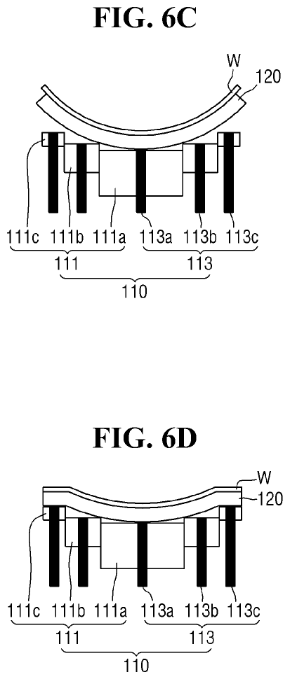

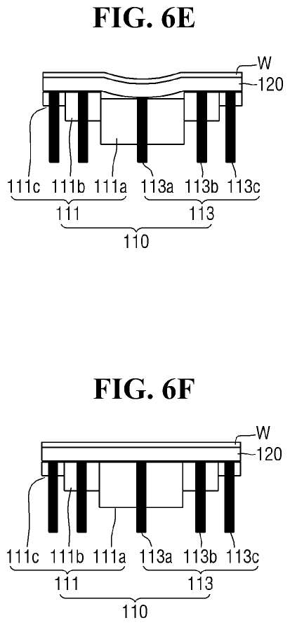

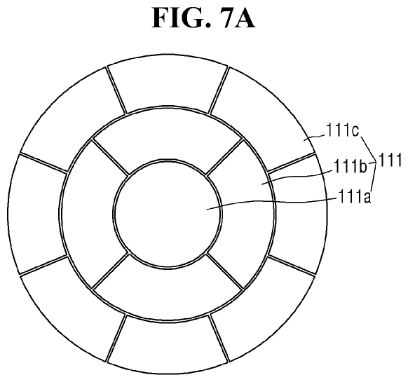

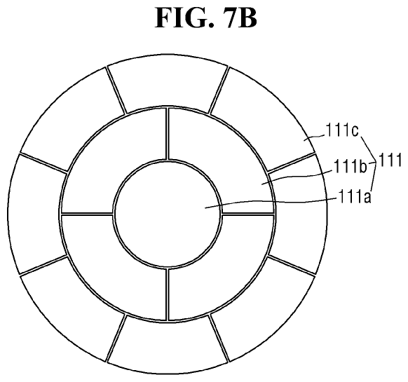

FIGS. 5A, 5B, 5C, 5D, 5E, and 5F and FIGS. 6A, 6B, 6C, 6D, 6E and 6F are diagrams for explaining deformation of the support member according to operation of the second sensor of the semiconductor package manufacturing apparatus according to some example embodiments.

FIGS. 5A, 5B, 5C, 5D, 5E, and 5F are diagrams showing a process in which a second type of warped substrate W, which will be described later, is settled on the support member 110 according to some example embodiments.

Referring to FIG. 5A, the substrate W on which the mold layer 120 is formed may be provided on the support member 110. The support member 110 may include adsorbing portion 111 and second sensor 113. The adsorbing portion 111 may include the plurality of divided regions 111a, 111b and 111c. The second sensor 113 may include second sensors 113a, 113b and 113c that measure a distance between each of the plurality of divided regions 111a, 111b and 111c and the substrate W. The heights of the upper surfaces of each of the plurality of divided regions 111a, 111b and 111c may be the same.

Referring to FIG. 5B, the distance between each of the plurality of divided regions 111a, 111b and 111c and the substrate W may be measured by a second sensor 113. The second sensor 113 may be, for example, a laser distance sensor. As will be described later, the second sensor 113 may include an inner sensor 113a, an intermediate sensor 113b, and an outer sensor 113c corresponding to each of an inner portion 111a, an intermediate portion 111b, and an outer portion 111c of the support member 110.

Referring to FIG. 5C, the support member 110 may be deformed to correspond to the warpage shape of the substrate W based on the distances measured by the second sensor 113. Specifically, the height of the inner portion 111a of the support member 110 corresponding to the inner region of the substrate W may be adjusted to be located at the uppermost portion. The heights of the intermediate portion 111b and the outer portion 111c of the support member 110, corresponding to the intermediate region and the outer region of the substrate W, may be adjusted to be located at levels lower than the inner portion 111a.

Referring to FIG. 5D, the inner portion 111a may vacuum-adsorb the inner region of the substrate W. Further, referring to FIG. 5E, the intermediate portion 111b may vacuum-adsorb the intermediate region of the substrate W. Further, referring to FIG. 5F, the outer portion 111c may vacuum-adsorb the outer region of the substrate W. As a result, the inner region, the intermediate region, and the outer region of the substrate W may be sequentially adsorbed to the support member 110.

FIGS. 6A, 6B, 6C, 6D, 6E and 6F are diagrams showing a process in which a third type of warped substrate W, which will be described later, is settled on the support member 110 according to some example embodiments.

Referring to FIG. 6A, the substrate W on which the mold layer 120 is formed may be provided on the support member 110. The support member 110 may include second sensors 113a, 113b and 113c that measure the distance between each of the plurality of divided regions 111a, 111b and 111c and the substrate W. The heights of the upper surfaces of each of the plurality of divided regions 111a, 111b and 111c may be the same.

Referring to FIG. 6B, the distance between each of the plurality of divided regions 111a, 111b and 111c and the substrate W may be measured by the second sensor 113.

Referring to FIG. 6C, the support member 110 may be deformed to correspond to the warpage shape of the substrate W based on the distances measured by the second sensor 113. Specifically, the height of the outer portion 111c of the support member 110 corresponding to the outer region of the substrate W may be adjusted to be located at the uppermost portion. The heights of the intermediate portion 111b and the inner portion 111a of the support member 110, corresponding to the intermediate region and the inner region of the substrate W, may be adjusted to be located at levels lower than the outer portion 111c.

Referring to FIG. 6D, the outer portion 111c may vacuum-adsorb the outer region of the substrate W. Further, referring to FIG. 6E, the intermediate portion 111b may vacuum-adsorb the intermediate region of the substrate W. Further, referring to FIG. 6F, the inner portion 111a may vacuum-adsorb the inner region of the substrate W. As a result, the outer region, the intermediate region, and the inner region of the substrate W may be sequentially adsorbed to the support member 110.

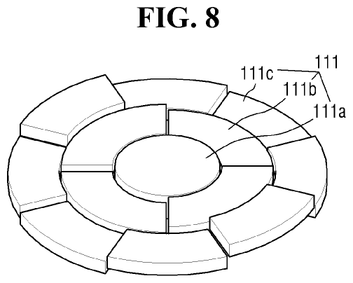

FIGS. 7A and 7B are schematic diagrams showing the support member of the semiconductor package manufacturing apparatus according to some example embodiments from above. FIG. 8 is a schematic diagram showing the support member of the semiconductor package manufacturing apparatus according to some example embodiments is seen from the side.

Referring to FIG. 7A, an adsorbing portion 111 of the support member 110 may include a plurality of divided regions 111a, 111b and 111c for adsorbing the substrate W. The adsorbing portion 111 adsorbs the substrate W for each of the plurality of divided regions 111a, 111b and 111c to correspond to the shape of the substrate W.

The adsorbing portion 111 includes an inner portion 111a placed on the innermost side of the support member 110, an outer portion 111c placed to surround the inner portion 111a, and an intermediate portion 111b placed between the inner portion 111a and the outer portion 111c.

The inner portion 111a may be made up of a single region. The intermediate portion 111b may be made up of four divided regions between the inner portion 111a and the outer portion 111c. The outer portion 111c may be made up of seven divided regions. Areas of each region of the inner portion 111a, the intermediate portion 111b, and the outer portion 111c may be the same as or different from each other. Also, the quantity and area of each region of the inner portion 111a, the intermediate portion 111b, and the outer portion 111c may be configured in various ways to correspond to the warpage shape of the substrate W.

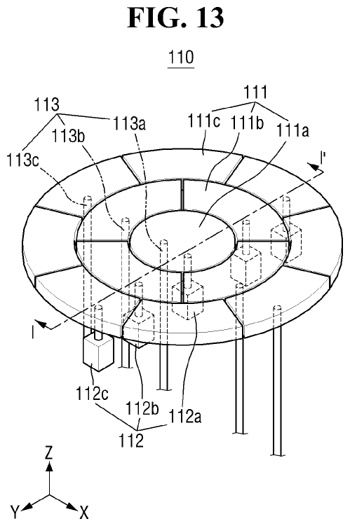

Each of the divided regions may be moved by a driving portion 112, which will be described later, in a direction perpendicular to the upper surface of the substrate W, that is, in a vertical direction (Z direction of FIG. 13), or may be rotated in a direction aligned with the upper surface of the substrate W.

Referring to FIG. 7B, only a part of the plurality of divided regions 111a, 111b and 111c may be rotated. For example, the regions of the inner portion 111a and the outer portion 111c do not rotate, and only the regions of the intermediate portion 111b may rotate by a predetermined angle. However, example embodiments are not limited thereto, and a rotation angle of each region of the inner portion 111a, the intermediate portion 111b, and the outer portion 111c may be configured in various ways to correspond to the warpage shape of the substrate W. After rotating each of the plurality of divided regions 111a, 111b and 111c of the support member 110 in accordance with the warpage shape of the substrate W, the substrate W may be settled on the support member 110.

Referring to FIG. 8, only a part of the plurality of divided regions 111a, 111b and 111c may be moved in the vertical direction. For example, only a part of the regions of the inner portion 111a and the intermediate portion 111b and a part of the regions of the outer portion 111c may move in the vertical direction by a predetermined distance. However, example embodiments are not limited thereto, and movement or movement distance of each region of the inner portion 111a, the intermediate portion 111b, and the outer portion 111c in the vertical direction may be configured in various ways to correspond to the warpage shape of the substrate W.

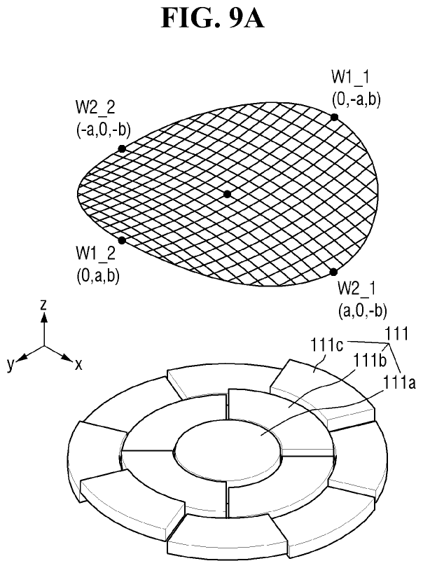

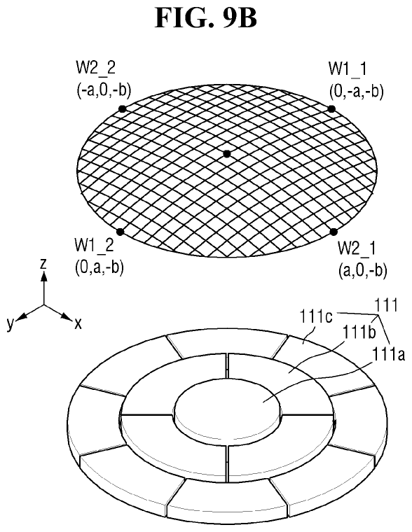

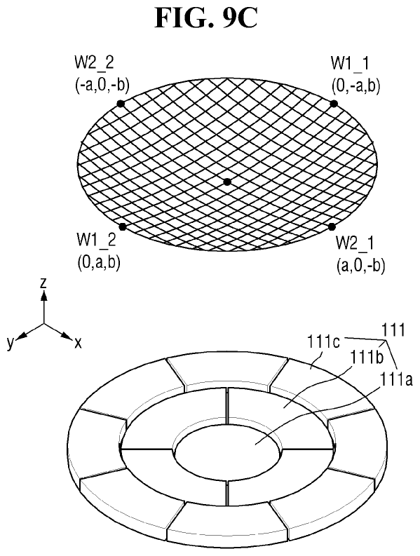

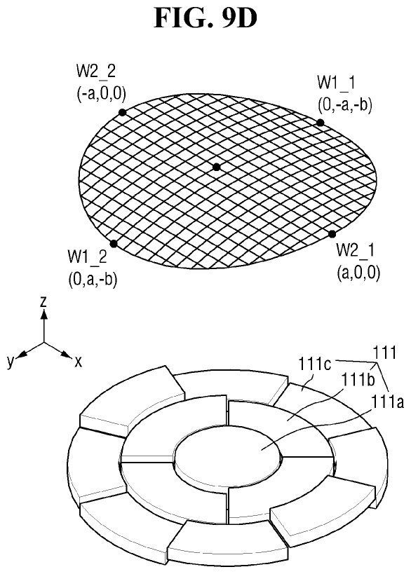

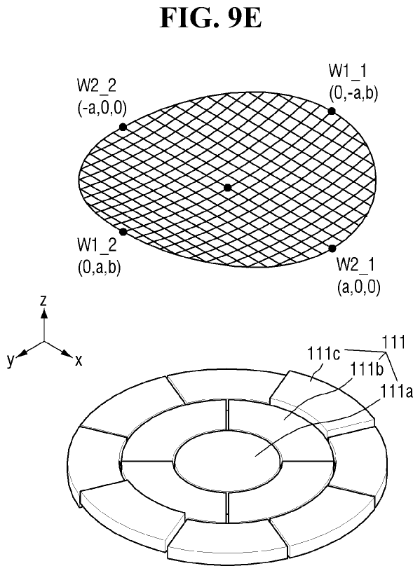

FIGS. 9A, 9B, 9C, 9D and 9E are diagram which schematically shows the type of warpage of a substrate according to some example embodiments, and the support member deformed to correspond to each type of warpage.

In FIGS. 9A, 9B, 9C, 9D and 9E, the warpage type of the substrate W will be described, using a (x, y, z) coordinate system in which the center of the substrate W corresponds to (0,0,0). In this case, the four edge regions of the substrate W may be referred to as 1_1 stage (W1_1), 1_2 stage (W1_2), 2_1 stage (W2_1), and 2_2 stage (W2_2).

Referring to FIG. 9A, in the case of the first type of warped substrate W, the heights of the 1_1 stage (W1_1) and the 1_2 stage (W1_2) of the substrate W in the z direction are higher than the center of the substrate W, and the heights of the 2_1 stage (W2_1) and the 2_2 stage (W2_2) of the substrate W in the z direction are lower than the center of the substrate W.

The height in the z direction of the region of the adsorbing portion 111 corresponding to the 1_1 stage (W1_1) and the 1_2 stage (W1_2) of the substrate W may be controlled to be high, and the height in the z direction of the region of the adsorbing portion 111 corresponding to the 2_1 stage (W2_1) and the 2_2 stage (W2_2) of the substrate W may be controlled to be low.

Further, the height in the z direction of the substrate W drops from the 1_2 stage (W1_2) to the 2_1 stage (W2_1). The height in the z direction of the regions of the adsorbing portion 111 between the 1_2 stage (W1_2) and the 2_1 stage (W2_1) may be controlled to gradually decrease.

Referring to FIG. 9B, in the second type of warped substrate W, heights of the 1_1 stage (W1_1), the 1_2 stage (W1_2), the 2_1 stage (W2_1) and the 2_2 stage (W2_2) of the substrate W in the z direction may be lower than the center of the substrate W.

The height in the z direction of the region of the adsorbing portion 111 corresponding to the 1_1 stage (W1_1), the 1_2 stage (W1_2), the 2_1 stage (W2_1) and the 2_2 stage (W2_2) of the substrate W may be formed to be lower than the height of the region of the adsorbing portion 111 corresponding to the center of the substrate W.

Referring to FIG. 9C, in a third type of warped substrate W, heights of the 1_1 stage (W1_1), the 1_2 stage (W1_2), the 2_1 stage (W2_1) and the 2_2 stage (W2_2) of the substrate W in the z direction may be higher than the center of the substrate W.

The height in the z direction of the region of the adsorbing portion 111 corresponding to the 1_1 stage (W1_1), the 1_2 stage (W1_2), the 2_1 stage (W2_1) and the 2_2 stage (W2_2) of the substrate W may be formed to be higher than the height of the region of the adsorbing portion 111 corresponding to the center of the substrate W.

Referring to FIG. 9D, in a fourth type of warped substrate W, the heights of the 1_1 stage (W1_1) and the 1_2 stage (W1_2) of the substrate W in the z direction may be lower than the heights of the 2_1 stage (W2_1) and the 2_2 stage (W2_2) of the substrate W in the z direction.

The heights in the z direction of the region of the adsorbing portion 111 corresponding to the 1_1 stage (W1_1) and the 1_2 stage (W1_2) of the substrate W may be formed to be lower than the heights of the region of the adsorbing portion 111 corresponding to the 2_1 stage (W2_1) and the 2_2 stage (W2_2) of the substrate W.

Further, the height in the z direction of the substrate W drops from the 2_1 stage (W2_1) to the 1_2 stage (W1_2). The height in the z direction of the regions of the adsorbing portion 111 between the 2_1 stage (W2_1) and the 1_2 stage (W1_2) may be controlled to gradually decrease.

Referring to FIG. 9E, in a fifth type of warped substrate W, the heights of the 1_1 stage (W1_1) and the 1_2 stage (W1_2) of the substrate W in the z direction may be higher than the heights of the 2_1 stage (W2_1) and 2_2 stage (W2_2) of the substrate W in the z direction.

The height in the z direction of the regions of the adsorbing portion 111 corresponding to the 1_1 stage (W1_1) and the 1_2 stage (W1_2) of the substrate W may be formed to be higher than the heights of the regions of the adsorbing portion 111 110 corresponding to the 2_1 stage (W2_1) and the 2_2 stage (W2_2) of the substrate W.

Further, the height in the z direction of the regions of the adsorbing portion 111 may be controlled to gradually increase from the 2_1 stage (W2_1) to the 1_2 stage (W1_2). The height in the z direction of the regions of the adsorbing portion 111 between the 2_1 stage (W2_1) to the 1_2 stage (W1_2) may be formed to gradually increase.

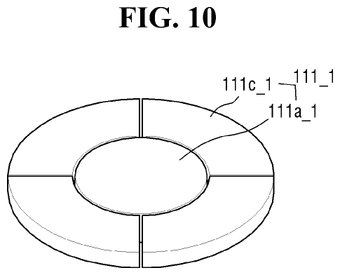

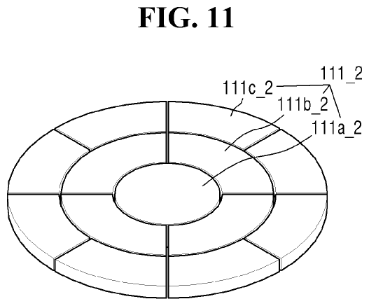

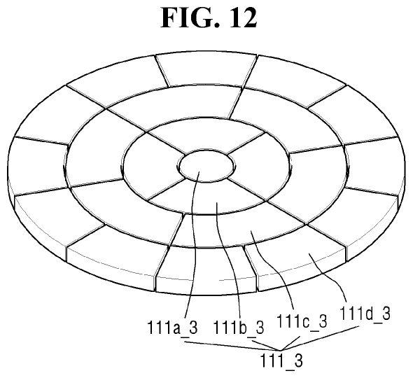

FIGS. 10 to 12 are diagrams showing the support member of the semiconductor package manufacturing apparatus according to some example embodiments.

Referring to FIG. 10, an adsorbing portion 111_1 includes an inner portion 111a_1 placed on the innermost side of the adsorbing portion 111_1, and an outer portion 111c_1 placed to surround the inner portion 111a_1.

The inner portion 111a_1 may be made up of one region. The outer portion 111c_1 may be made up of four divided regions. However, example embodiments are not limited thereto, and the number and area of each region of the inner portion 111a_1 and the outer portion 111c_1 may be configured in various ways to correspond to the warpage shape of the substrate W.

Referring to FIG. 11, an adsorbing portion 111_2 includes an inner portion 111a_2 placed on the innermost side of the adsorbing portion 111_2, an outer portion 111c_2 placed to surround the inner portion 111a_2, and an intermediate portion 111b_2 placed between the inner portion 111a_2 and the outer portion 111c_2.

The inner portion 111a_2 may be made up of one region. The intermediate portion 111b_2 may be made up of four divided regions between the inner portion 111a_2 and the outer portion 111c_2. The outer portion 111c_2 may be made up of eight divided regions. However, example embodiments are not limited thereto, and the number and area of each region of the inner portion 111a_2, the intermediate portion 111b_2, and the outer portion 111c_2 may be configured in various ways to correspond to the warpage shape of the substrate W.

Referring to FIG. 12, an adsorbing portion 111_3 includes an inner portion 111a3 placed on the innermost side of the adsorbing portion 111_3, an outer portion 111d_3 placed to surround the inner portion 111a_3, and a first intermediate portion 111b_3 and a second intermediate portion 111c_3 placed between the inner portion 111a_3 and the outer portion 111d_3.

The inner portion 111a_3 may be made up of one region. The first intermediate portion 111b_3 may be made up of four divided regions. The second intermediate portion 111c_3 may be made up of six divided regions. The outer portion 111d_3 may be made up of twelve divided regions. However, example embodiments are not limited thereto, and the number and area of each region of the inner portion 111a_3, the first intermediate portion 111b_3, the second intermediate portion 111c_3, and the outer portion 111d_3 may be configured in various ways to correspond to the warpage shape of is the substrate W.

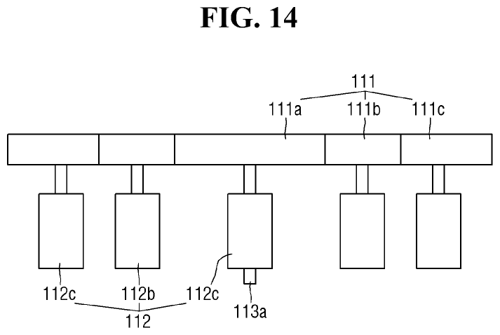

FIG. 13 is a diagram for explaining an adsorbing portion and a driving portion of the support member according to some example embodiments. FIG. 14 is a diagram showing a cross section along a line IT of FIG. 13.

Although FIG. 13 shows that a plurality of driving portions 112a, 112b and 112c are placed only in partial regions of the plurality of divided regions 111a, 111b and 111c to correspond to the partial regions for convenience of explanation, example embodiments are not limited thereto. For example, the driving portion 112 may include portions which are placed to correspond to all of the plurality of divided regions 111a, 111b, and 111c. That is, the driving portion 112 may individually move each of the plurality of divided regions 111a, 111b, and 111c in the vertical direction. The driving portion 112 may also rotate one or more of the plurality of divided regions 111a, 111b, and 111c. Further, in some example embodiments, the plurality of divided regions may indicate all the regions (for example, thirteen divided regions) included in the inner portion 111a, the intermediate portion 111b, and the outer portion 111c.

Although FIG. 13 shows that the plurality of second sensors 113a, 113b and 113c are placed only in partial regions of the plurality of divided regions 111a, 111b and 111c to correspond to the partial regions, example embodiments are not limited thereto, and the second sensor 113 may include portions which are placed to correspond to all of the plurality of divided regions 111a, 111b and 111c.

Referring to FIG. 13, the support member 110 includes a driving portion 112 that receives information about the shape of the substrate W and drives the adsorbing portion 111 for each of the plurality of divided regions 111a, 111b and 111c to correspond to the shape of the substrate W. The driving portion 112 may be placed below the adsorbing portion 111. The driving portion 112 may be, for example, a motor, a piezoelectric element, a cylinder, or the like. The driving portion 112 is not particularly limited as long as it may provide power capable of moving the support member 110.

The support member 110 includes a second sensor 113 that measures the distance between each of the plurality of divided regions 111a, 111b and 111c and the substrate W. The second sensor 113 may be formed to penetrate the adsorbing portion 111 of the support member 110.

The support member 110 may further include a shaft guide that penetrates each of the plurality of divided regions 111a, 111b and 111c. The shaft guide may serve to adjust the alignment between the plurality of divided regions 111a, 111b and 111c.

Referring to FIG. 14, each of the plurality of divided regions 111a, 111b and 111c maintains a status in which the same heights of the upper surfaces are matched up equally, before the substrate W having the warpage is provided. After that, when the substrate W having the warpage is provided, the optimum movement distance of each of the plurality of divided regions 111a, 111b and 111c may be calculated on the basis of the information about the shape of the substrate W measured in advance by the scan module 200.

Alternatively, the distance between each of the plurality of divided regions 111a, 111b and 111c and the substrate W may be measured by the second sensor 113 that may measure the lower part of the substrate W. After that, the driving portion 112 may move each of the plurality of divided regions 111a, 111b and 111c to the optimum position.

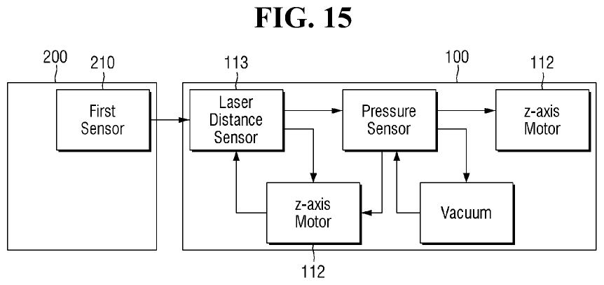

FIG. 15 is a diagram which schematically shows the semiconductor package manufacturing method using the semiconductor package manufacturing apparatus according to some example embodiments.

First, in order to attach the solder balls SB to one surface of the substrate W, the substrate W is settled on the support member 110.

Referring to FIG. 15, information about the warpage shape of the substrate W may be measured in advance by the first sensor 210 of the scan module 200, and the optimum movement distances to move each of the plurality of divided regions 111a, 111b and 111c to optimum positions are calculated depending on the warpage shape.

The distance between each of the plurality of divided regions 111a, 111b and 111c and the substrate W may be measured by the second sensor 113. The second sensor 113 may be a laser distance sensor.

The plurality of divided regions 111a, 111b and 111c may be moved in the vertical direction (z direction) up to the optimum position by the driving portion 112. For example, the driving portion 112 may be a motor (z-axis motor) that makes the plurality of divided regions 111a, 111b and 111c movable in the z direction.

The support member 110 may vacuum-adsorb the substrate W when each of the plurality of divided regions 111a, 111b, and 111c reaches the maximum distance at which the vacuum adsorption is enabled. The vacuum adsorption of the substrate W by the support member 110 may include maintenance of the vacuum status until a constant pressure is reached by the pressure sensor. The support member 110 may adsorb the substrate W for each of the plurality of divided regions 111a, 111b and 111c to correspond to the shape of the substrate W.

When the vacuum adsorption is completed, each of the plurality of divided regions 111a, 111b, and 111c may relocate to the position before the movement to bring the substrate W into a fixed position. The driving portion 112 may move each of the plurality of divided regions 111a, 111b and 111c in the vertical direction (z direction) to the position before the movement. For example, each of the plurality of divided regions 111a, 111b and 111c may be moved to the same level.

The substrate W may be detached from each of the plurality of divided regions 111a, 111b and 111c in a status in which the plurality of divided regions 111a, 111b and 111c are relocated to correspond to the warpage shape of the substrate W. That is, when the substrate W is detached from the support member 110, the support member 110 may be moved to the shape of the warpage originally possessed by the substrate W and then be released. As a result, the substrate W may be stably attached to and detached from each of the plurality of divided regions 111a, 111b, and 111c, while minimizing a detachment phenomenon of the solder balls SB.

A process of attaching and detaching the support member 110 and the substrate W may be sequentially performed for each of the plurality of divided regions 111a, 111b, and 111c.

While aspects of example embodiments have been particularly shown and described, it will be understood that various changes in form and details may be made therein without departing from the spirit and scope of the following claims.

What is claimed is:

1. A semiconductor package manufacturing method which uses a semiconductor package manufacturing apparatus including:
a chuck;
a solder device configured to attach solder balls to a substrate provided on the chuck; and
a scanning device configured to provide information about a shape of the substrate to the chuck,
wherein the chuck comprises an adsorbing portion comprising a plurality of divided regions, each of which is configured to adsorb the substrate, and a driver configured to drive each of the plurality of divided regions,
the semiconductor package manufacturing method comprising:
driving each of the plurality of divided regions to correspond to the shape of the substrate based on the information using the driver.

2. The semiconductor package manufacturing method of claim 1, wherein each of the plurality of divided regions of the adsorbing portion is configured to adsorb the substrate at a position corresponding to the shape of the substrate.

3. The semiconductor package manufacturing method of claim 1, wherein the driver is further configured to move each of the plurality of divided regions along a direction perpendicular to an upper surface of the substrate.

4. The semiconductor package manufacturing method of claim 1, wherein the driver is further configured to rotate the plurality of divided regions along a direction parallel to an upper surface of the substrate.

5. The semiconductor package manufacturing method of claim 1, wherein the scanning device comprises a sensor configured to obtain the information about the shape of the substrate, and provide warpage information to the chuck about a warpage type of the substrate, movement of each of the plurality of divided regions, and a movement distance.

6. The semiconductor package manufacturing method of claim 1, wherein the chuck comprises a sensor configured to measure a distance between each of the plurality of divided regions and the substrate, and
wherein the driver is further configured to drive each of the plurality of divided regions based on the distance.

7. The semiconductor package manufacturing method of claim 6, wherein the sensor extends into the chuck.

8. The semiconductor package manufacturing method of claim 1, wherein the semiconductor package manufacturing apparatus further comprising an inspection device configured to:
identify whether the solder balls are attached to the substrate and a location corresponding to a missing solder ball; and
provide a solder ball to the location corresponding to the missing solder ball.

9. A semiconductor package manufacturing method comprising:
attaching solder balls to a substrate provided on a chuck, the chuck comprising a plurality of divided regions;
providing information about a warpage shape of the substrate to the chuck; and
individually controlling positions of each of the plurality of divided regions based on the information.

10. The semiconductor package manufacturing method of claim 9, further comprising adsorbing the substrate using each of the plurality of divided regions.

11. The semiconductor package manufacturing method of claim 9, wherein the individually controlling the positions of each of the plurality of divided regions comprises moving the plurality of divided regions along a vertical direction to correspond to the warpage shape of the substrate.

12. The semiconductor package manufacturing method of claim 9, further comprising rotating the plurality of divided regions based on the warpage shape of the substrate.

13. The semiconductor package manufacturing method of claim 9, further comprising:
controlling a sensor to obtain the information about the warpage shape of the substrate; and
transmitting the information about the warpage shape of the substrate, movement of each of the plurality of divided regions, and a movement distance to the chuck.

14. The semiconductor package manufacturing method of claim 9, further comprising:
controlling a sensor to obtain a distance between each of the plurality of divided regions and the substrate; and
adjusting heights of the plurality of divided regions based on the distance.

15. The semiconductor package manufacturing method of claim 9, wherein the plurality of divided regions are provided at an initial position when the substrate is attached to the chuck, and
wherein the semiconductor package manufacturing method further comprises:
relocating the plurality of divided regions to the initial position; and
detaching the substrate from the chuck while the plurality of divided regions are provided at the initial position.

16. The semiconductor package manufacturing method of claim 9, further comprising:
identifying the solder balls that are attached to the substrate; and
providing a solder ball to a location corresponding to a missing solder ball.

17. A semiconductor package manufacturing method which uses a semiconductor package manufacturing apparatus including: a chuck;
a solder device configured to attach solder balls to a substrate provided on the chuck; and a scanning device configured to provide information about a shape of the substrate to the solder device, wherein the chuck includes an adsorbing portion including a plurality of divided regions, each of which is configured to adsorb the substrate, and a driver configured to drive each of the plurality of divided regions, the scanning device includes a first sensor, the chuck includes a second sensor, the semiconductor package manufacturing method comprising:
providing the substrate on the chuck;
obtaining information indicating a warpage shape of the substrate using the first sensor;
identifying a movement distance for each of the plurality of divided regions according to the information;
measuring a distance between each of the plurality of divided regions and the substrate using the second sensor;
moving each of the plurality of divided regions to an initial position based on the movement distance using the driver;
adsorbing the substrate to the chuck based on each of the plurality of divided regions reaching an adsorption distance at which vacuum adsorption is enabled;
moving each of the plurality of divided regions back to the initial position; and
detaching the substrate from the plurality of divided regions while positioned at the initial position.

18. The semiconductor package manufacturing method of claim 17, wherein the adsorbing the substrate comprises controlling the plurality of divided regions to correspond to the shape of the substrate.

19. The semiconductor package manufacturing method of claim 17, wherein the adsorbing the substrate comprises maintaining a vacuum status until a constant pressure is reached based on a pressure sensor reading.

20. The semiconductor package manufacturing method of claim 17, further comprising identifying a number of solder balls on the substrate; and providing solder ball to a location corresponding to a missing solder ball.
